(19) United States
(12) Patent Application Publication
(10) Pub. No.: US 2011/0182048 A1
(43) Pub. Date: Jul. 28, 2011

(54) ELECTRONIC ASSEMBLY AND METHOD FOR ITS MANUFACTURE

(76) Inventors: Walter Roethlingshoefer, Reutlingen (DE); Ulrich Goebel, Reutlingen (DE)

(21) Appl. No.: 12/737,445

(22) PCT Filed: Jun. 16, 2009
(86) PCT No.: PCT/EP2009/057409

§ 371 Date: Apr. 6, 2011

(30) Foreign Application Priority Data
Jul. 17, 2008 (DE) 10 2008 040 488.8

(51) Int. Cl. H05K 7/00

(52) U.S. Cl. 361/820

(57) ABSTRACT

An electronic assembly has at least one conductor substrate carrying components, which conductor substrate is surrounded by a mechanical protection. The conductor substrate is encased using a molding compound as a mechanical protection and is contacted by at least one intrinsically stiff, spring-elastic electrical connection conductor, the connection conductor being embedded in the molding compound, at least in sections.

### BACKGROUND OF THE INVENTION

1. Field of the Invention

The present invention relates to an electronic assembly having at least one conductor substrate carrying components, which conductor substrate is surrounded by a mechanical protection, and a manufacturing method directed to the same.

2. Description of the Related Art

Electronic assemblies are accommodated in housings for their protection. In particular in hybrid technology, equipped and bonded substrates are installed in prefabricated housings via complex assembly processes, for which the substrate is cemented to a base plate, a housing is assembled, the substrate is bonded, the substrate is cured and a cover is mounted or the housing is completely assembled in a typical sequence of steps. On the one hand, the relatively high manufacturing expense and the high vertical integration are disadvantageous in this connection and each is associated with considerable costs. On the other hand, the dimensions achievable using the given housing shapes are unfavorably large.

### BRIEF SUMMARY OF THE INVENTION

An object of the present invention is to provide an electronic assembly which provides a maximum amount of circuit density in a small space in a protective housing and which may be manufactured simply and cost-effectively. In particular, good removal of heat from the circuit components should also be achieved.

To this end, an electronic assembly having at least one conductor substrate carrying components, which conductor substrate is surrounded by a mechanical protection, is described. It is provided for the conductor substrate to be surrounded by a molding compound as a mechanical protection and is contacted by at least one intrinsically stiff, spring-elastic electrical connection conductor, the connection conductor being embedded in the molding compound at least in sections. The embedding of the connection conductor (for example, a stamped grid) in the molding compound ensures that it is in a correct position and immovably fixed. The conductor substrate itself is surrounded by the molding compound as a mechanical protection, making a separate housing, as is known from the related art, completely unnecessary.

According to another example embodiment, an outer side of the conductor substrate projects out of the molding compound, at least in sections, for heat dissipation. The projection of the outer side from the molding compound makes it possible to remove heat from the circuit arrangement in a very simple manner. In this connection, heat is dissipated via the air surrounding the electronic assembly in the area of the projecting outer side and through the conductor substrate. Special housings for heat dissipation as are known in the related art may be eliminated.

In another example embodiment, one outer side or side of the conductor substrate is situated on a base body, in particular a base plate, which projects from the molding compound at least in sections for heat dissipation. The positioning on a base plate or a base body makes it possible to remove heat in/across this base body over a large area, in particular when it is made from a material which conducts heat very well, for example, a metal. If the base body is positioned to project out of the molding compound, it is possible to remove heat from the electronic assembly particularly well without a special manufacturing expense being necessary for this.

In another example embodiment, at least two conductor substrates are situated at a distance from one another, the connection conductor being situated between the conductor substrates and being electrically connected to both conductor substrates. This makes it possible to achieve a particularly high packaging density of the electronic assembly, the positioning of the connection conductor between the conductor substrates and the simultaneous contacting of both conductor substrates ensuring very simple, particularly cost-effective multiple contacting. Preferably, the two conductor substrates are situated parallel or roughly parallel to one another, the connection conductor being positioned roughly at the center between the conductor substrates. Nonetheless, this configuration makes it possible to remove heat very effectively.

Preferably, at least one section of the connection conductor projects out of the molding compound as an electrical terminal. This makes it possible to achieve not only very simple multiple contacting but also to integrate the function of a plug connector for the electronic assembly at the same time. Additional components, for example, male connectors, are unnecessary for this purpose.

In another example embodiment, the conductor substrate is a printed circuit board. Printed circuit boards are adequately known in the related art. They may be equipped in a particularly simple manner and integrated in the assembly. According to another example embodiment, the connection conductor is in contact with the conductor substrate under pretensioning. For the purpose of contacting, the connection conductor is placed in contact with the conductor substrate with pretensioning, making it possible for the conductor substrate to be contacted via the elastic design of the connection conductor. In a very simple manner, the pretensioning is achieved via the spatial positioning of the conductor substrate and the connection conductor relative to one another.

In an example embodiment, the connection conductor is sintered with the conductor substrate via a sintered connection and thus electrically and mechanically joined. In particular for the purpose of reliability and use under extreme conditions, the sintered connection is made via an interdiffusion of sintered materials which is of particular advantage for the mechanical anchoring and electrical contacting of the connection conductor and conductor substrate. While the contacting may be achieved via purely mechanical spring contacting in less demanding applications, as described at the outset, a sintered connection is extraordinarily advantageous for achieving higher operating reliability for applications having rapid changes of temperature and a large range of temperatures and, for example, under mechanical stress (shaking or the like).

It is particularly preferred that the sintered connection is a low temperature sintered connection. A low temperature sintered connection is in this case one which may be produced using low temperature sintering metal, for example, silver nanopowder, which, at temperatures in a typical range of approximately 200° C., ensures a mechanical connection via interdiffusion between the sintering locations to be contacted. Ideally, the particular contact points of the inserts, i.e., the connection conductor and/or conductor substrate, are coated with nickel and/or gold to support the interdiffusion of silver and accordingly the mechanical anchoring. Optionally, the contact points may also be coated with nickel and/or palladium and/or gold and/or an alloy of these metals.

In an example embodiment, the conductor substrate is a low temperature cofire ceramic (LTCC). A low temperature cofire ceramic is one in which the conductor substrate is built up in several layers which, in contrast to, for example, the so-called thick-film technique, may be produced in a single operation (cofire). The packaging of such hybrid modules in particular is associated with considerable expense in the related art and with relatively large housing designs, the removal of heat only being possible via housings of complex design. These disadvantages may be resolved using the specific embodiment according to the present invention.

Furthermore, a method for manufacturing an electronic assembly having at least one conductor substrate carrying components, which conductor substrate is surrounded by a mechanical protection, is described, the following steps being performed:
a) placing the conductor substrate in a molding tool,
b) placing an intrinsically stiff, spring-elastic electrical connection conductor in diametric opposition to the conductor substrate, the connection conductor being in contact with the conductor substrate under pretensioning, at least in sections,
c) encasing the configuration thus obtained with molding compound to form the mechanical protection.

Accordingly, the conductor substrate is placed in the mold tool in which the molding later takes place. In relation to this, the connection conductor is situated diametrically opposite the conductor substrate, the connection conductor being in contact with the conductor substrate specifically at the locations at which the contacting between the connection conductor and the conductor substrate is to be made. If this configuration is present, molding compound is added to the molding tool to [obtain] the mechanical protection by encasing the thus obtained configuration of conductor substrate and connection compound to form the mechanical protection. In contrast to the related art, an existing housing present as a separate component is thus not used for packaging. The mechanical protection (thus in the broadest sense a housing to be newly produced) is created at the moment at which the described configuration is encased by the molding compound.

Preferably, a method is provided in which contact points are formed on the conductor substrate using a metal which is sintered at low temperatures, in particular silver nanopowder and/or nickel and/or palladium and/or gold or a combination of metals for sintering in areas of the connection conductors before the sequence of operations described at the outset.

Preferably, the above-referenced areas are sintered during the extrusion coating using the molding compound and/or during a heating of the molding compound. No separate method step is required for the sintering, which is specifically a low temperature sintering taking place in a temperature range in which the encapsulation using molding compound is performed. The molding compound has, for example, a temperature of approximately 300° C., the sintering already beginning at temperatures of approximately 200° C.

In an example embodiment of the method, the conductor substrate is joined to and/or placed on a base body, in particular a thermally conductive base plate, before molding. This makes it possible to remove a slight amount of heat. In a particularly preferred embodiment of the method, two conductor substrates are placed in diametric opposition to one another before being encased by a molding compound to achieve a high packaging density, the connection conductor being situated between the two conductor substrates for the simultaneous contacting of both conductor substrates, at least in sections. Of course, the connection conductor may also be situated to project out of the molding compound, at least in sections, to form a plug connector.

Embodiments of the method are of course also possible in which more than two conductor substrates are in each case situated in diametric opposition to one another, for example, three, four or even more, and a connection conductor being situated between each of them for the simultaneous contacting, at least in sections, of diametrically opposed conductor substrates, it being possible for the particular connection conductor to project out of the molding compound simultaneously for outside contacting. In the interest of optimal removal of heat, the conductor substrates requiring the greatest removal of heat are each situated at the top and bottom of such a stack, so that they project from the molding compound, at least in sections, or they may be formed having a base plate projecting out from the molding compound, at least in sections.

In another example embodiment of the method, the pretensioning of the connection conductor is applied for contacting at least one conductor substrate when the molding tool is closed. This means that the connection conductor is in loose contact on top of or on the at least one conductor substrate and the pretensioning for the reliable contacting between the connection conductor and the conductor substrate results from the closing of the molding tool and the change in the relative position of the connection conductor and conductor substrate due to the closing of the molding tool, specifically a reduction in the distance; this achieves the desired pretensioning.

### BRIEF DESCRIPTION OF THE DRAWINGS

FIG. 1 shows an electronic assembly having two conductor substrates and a connection conductor situated between them which is also designed as a plug connector.

### DETAILED DESCRIPTION OF THE INVENTION

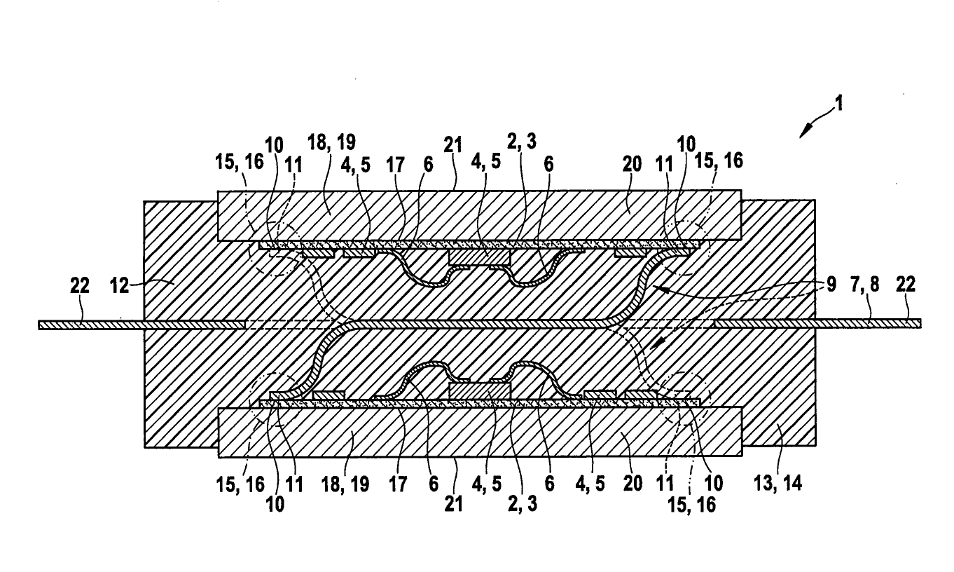

FIG. 1 shows an electronic assembly 1 having two conductor substrates 2, specifically, low temperature cofire ceramic (LTCC) 3, which are essentially situated diametrically opposed to one another in parallel. Electronic components 4, for example, semiconductors 5, are situated on the conductor substrates. They are soldered or bonded, for example via wire bonding 6, to conductor substrate 2. In this case, conductor substrates 2 are situated plane-parallel at a distance from one another so that a connection conductor 7 which is designed, for example, in the form of stamped grid 8, at least in sections, is situated between them. For the contacting of conductor substrates 2, the connection conductor has spring-elastic contact springs 9, which are preferably formed to be integral with connection conductor 7, for example, by stamping and shaping. Due to the distance of conductor substrates 2 from one another, contact springs 9 are in contact with contact points 10 of particular conductor substrate 2 under pretensioning. In the area of contact points 10, a low temperature sintering metal, in particular silver nanopowder and/or nickel and/or palladium and/or gold, is applied to conductor substrates 2. Preferably, such a low temperature sintering metal is also applied to ends 11 of contact springs 9 which are in contact with contact points 10. Electronic assembly 1 is designed in such a way that the prescribed configuration of conductor substrates 2 and connection conductor 7 is encased using a molding compound 12, a mechanical protection 13 for conductor substrate 2 and embedded connection conductor 7 being formed by a housing 14 which is created by the molding compound encasement. No separate housing as an independent component is necessary for this purpose. The encasement using molding compound 12 causes heat to be applied in the area of contact springs 9 and contact points 10, so that sintered connections 15 are formed there in the case of low temperature sintering metal. They are preferably low temperature sintered connections 16. This results not only in very good electrical contacting between contact springs 9 and accordingly connection conductor 7 with contact points 10, but also a mechanical fixation of connection conductor 7, specifically to particular conductor substrates 2 via contact springs 9. This design is very operationally reliable in particular under mechanical stress such as shaking. Rear sides 17 of conductor substrate 2 are in contact with base bodies 18, specifically base plate 19 made from a heat conducting material 20. After cooling, these base bodies project above molding 12, specifically with side 21 which faces away from applied conductor substrate 2. Without the need for additional heat sinks or a separate housing specifically designed for the particular application, this makes it possible to remove heat from electronic assembly 1 extremely well, advantageously increasing the operating reliability. Electronic assembly 1 shown here is particularly simple and cost-effective to manufacture using a molding tool (not shown), in particular if the mentioned pretensioning via which connection conductor 7 or its contact spring 9 is in contact with conductor substrates 2 or their contact points 10 is produced during molding or when the molding tool is closed. Furthermore, connection conductor 7 may be used as an electrical terminal 22 of electronic assembly 1 by situating connection conductor 7 in such a way that it projects out of molding compound 12, at least in sections. In a very advantageous and cost-effective way, this makes it possible to eliminate additional contacting means, for example, male connectors as are known from the related art. In particular in the field of microhybrid circuit technology, it is thus possible to produce operationally reliable electronic assemblies in an exceptionally cost-effective way.

1-16. (canceled)

17. An electronic assembly, comprising:
at least one conductor substrate carrying components;
a mechanical protection surrounding the conductor substrate, wherein a molding compound is the mechanical protection; and
at least one intrinsically stiff, spring-elastic electrical connection conductor contacting the conductor substrate, wherein the connection conductor is embedded in the molding compound, at least in sections.

18. The assembly as recited in claim 17, wherein one outer side of the conductor substrate projects out of the molding compound, at least in sections, for heat dissipation.

19. The assembly as recited in claim 18, wherein the one outer side of the conductor substrate is situated on a base plate projecting from the molding compound, at least in sections, for heat dissipation.

20. The assembly as recited in claim 19, wherein at least two conductor substrates are situated at a distance from one another, and wherein the connection conductor is situated between the two conductor substrates and electrically connected to the two conductor substrates.

21. The assembly as recited in claim 20, wherein at least one section of the connection conductor projects out of the molding compound as an electrical terminal.

22. The assembly as recited in claim 19, wherein the conductor substrate is a printed circuit board.

23. The assembly as recited in claim 19, wherein the connection conductor is in contact with the conductor substrate under pretensioning.

24. The assembly as recited in claim 19, wherein the connection conductor is sintered with the conductor substrate via a sintered connection.

25. The assembly as recited in claim 24, wherein the sintered connection is a low temperature sintered connection.

26. The assembly as recited in claim 19, wherein the conductor substrate is a low temperature cofire ceramic.

27. A method for manufacturing an electronic assembly, comprising:
a) placing at least one conductor substrate in a molding tool;
b) placing an intrinsically stiff, spring-elastic electrical connection conductor in diametric opposition to the conductor substrate, and contacting the connection conductor with the conductor substrate under pretensioning at least in sections; and
c) encasing the conductor substrate and the connection conductor with molding compound to form a mechanical protection surrounding the conductor substrate.

28. The method as recited in claim 27, wherein contact points are formed on the conductor substrate before step a) using a metal which sinters at a low temperature, wherein the metal includes at least one of silver nanopowder, nickel, palladium, and gold, for sintering with areas of the connection conductor.

29. The method as recited in claim 28, wherein the sintering is performed at least one of during extrusion coating using the molding compound and during a heating of the molding compound.

30. The method as recited in claim 28, wherein the conductor substrate is at least one of joined to a base body and placed on the base body before molding, wherein the base body is a thermally conductive base plate.

31. The method as recited in claim 28, wherein two conductor substrates are placed in diametric opposition to one another before being encased by the molding compound, and wherein the connection conductor is situated between the two conductor substrates for simultaneous contacting of both conductor substrates, at least in sections.

32. The method as recited in claim 28, wherein the pretensioning of the connection conductor is applied for contacting the at least one conductor substrate when the molding tool is closed.
